(19) United States
(12) Patent Application Publication
(10) Pub. No.: US 2023/0151950 A1
(43) Pub. Date: May 18, 2023

(54) FULL-SPECTRUM EYE-PROTECTING LED LAMP PANEL STRUCTURE AND LAMP

(71) Applicant: Huizhou King Star Technology Co., Ltd., Huizhou (CN)

(72) Inventors: SAIQUN LI, Huizhou (CN); JIEQIONG LIU, Huizhou (CN); XIAOXIA GUO, Huizhou (CN)

(21) Appl. No.: 17/989,872

(22) Filed: Nov. 18, 2022

(30) Foreign Application Priority Data
Nov. 18, 2021 (CN) 202111365944.5
Mar. 16, 2022 (CN) 202210257629.9

(51) Int. Cl. F21V 9/30

(52) U.S. Cl. CPC F21V 9/30; F21Y 2105/10

(57) ABSTRACT

A full-spectrum eye-protecting LED lamp panel structure, comprising a substrate on which multiple groups of SMD beads are arranged, and each group of SMD bead groups comprises a plurality of full-spectrum white light beads and at least one red light beads with a wavelength of 620-730 nm for adjusting spectrum. In addition, the present invention also discloses a lamp using the full-spectrum eye-protecting LED lamp panel structure, which can be ceiling lamps, desk lamps, floor lamps, panel lamps, classroom lamps, blackboard lamps, downlights, light strips, bulbs, etc. In the conventional lamp, the blue light value reaches more than 1.0. In the present application, after the red light bead is formulated, the blue light value in the spectrum can be lower than 0.8, which plays an eye protection function, and the color rendering index RA is greater than 96, and the effect of eye protection is achieved by reducing the blue light.

### CROSS-REFERENCE TO RELATED APPLICATIONS

This application claims the benefit and priority of Chinese patent application No. 202210257629.9, filed on Mar. 16, 2022; No. 202111365944.5, filed on Nov. 18, 2021, disclosure of which is hereby incorporated by reference in its entirety.

### TECHNICAL FIELD

The present application relates to the field of LED technology, in particular to a full spectrum eye-protecting LED lamp panel structure and a lamp.

### BACKGROUND

At present, most of the light panels of LED lamps are excited by one or more kinds of fluorescent powders by blue light beads, and finally the light emitted by the blue light and the fluorescent powders is mixed to form white light, so as to realize the lighting effect. The wavelength of blue light belongs to 380-500 nm, which belongs to high-energy visible light. Therefore, the blue light value of the spectrum of general LED will reach 1.0 or more (as shown in FIG. 1), while the relative radiation intensity of other wavelength ranges is very low. Although short-wave blue light is an important part of visible light, due to its short wavelength and high energy, it can directly penetrate the lens and reach the fundus and retina. Long-term exposure will adversely affect the naked eye.

### SUMMARY

In order to solve the above problems, the purpose of the present application is to provide a full-spectrum eye-protecting LED lamp panel structure capable of reducing the blue light spectrum and a lamp using the same.

The object of the present application is achieved by the following technical solutions:

A full-spectrum eye-protecting LED lamp panel structure, comprising a substrate on which multiple groups of SMD bead groups are arranged, and each group of the SMD bead groups comprises a plurality of full-spectrum white light beads and at least one red light beads with a wavelength of 620-730 nm for adjusting spectrum.

Furthermore, the number of the white light beads comprised in each group of the SMD bead group is 3-1.0 pieces.

Furthermore, the surface of the white light bead is provided with yellow phosphors.

Furthermore, the white light beads and the red light beads in the SMD bead groups are connected in series, and the SMD bead groups are connected in parallel to positive and negative terminals of a power supply.

The present application further discloses a lamp, Wherein the lamp is provided with the full-spectrum eye-protecting LED lamp panel structure as discussed above.

Compared with the prior art, the beneficial effects of the present application are:

The full-spectrum eye-protecting LED lamp panel structure according to the present application can be used in different lamp, such as ceiling lamps, desk lamps, floor lamps, panel lamps, classroom lamps, blackboard lamps, downlights, light strips, bulbs, etc. It can achieve eye protection function and meet different application scenarios or different user needs. In the conventional lamp, the blue light value reaches more than 1.0. In the present application, after the red light bead is formulated, the blue light value in the spectrum can be lower than 0.8, which plays an eye protection function, and the color rendering index RA is greater than 96, and the effect of eye protection is achieved by reducing the blue light.

### BRIEF DESCRIPTION OF DRAWINGS

FIG. 1 is a spectrogram when the existing LED lamp is illuminated;

FIG. 2 is a schematic diagram of the lamp panel structure of the present application;

FIG. 3 is a spectrogram when the present application is illuminated.

### REFERENCE SIGNS

10. Substrate; 20. SMD bead group; 21, White light bead; 22. Red light bead.

### DETAILED DESCRIPTION

The present application will be further described below with reference to the accompanying drawings and specific embodiments. It should be noted that, on the premise of no conflict, the embodiments or technical features described below can be combined arbitrarily to form new embodiments.

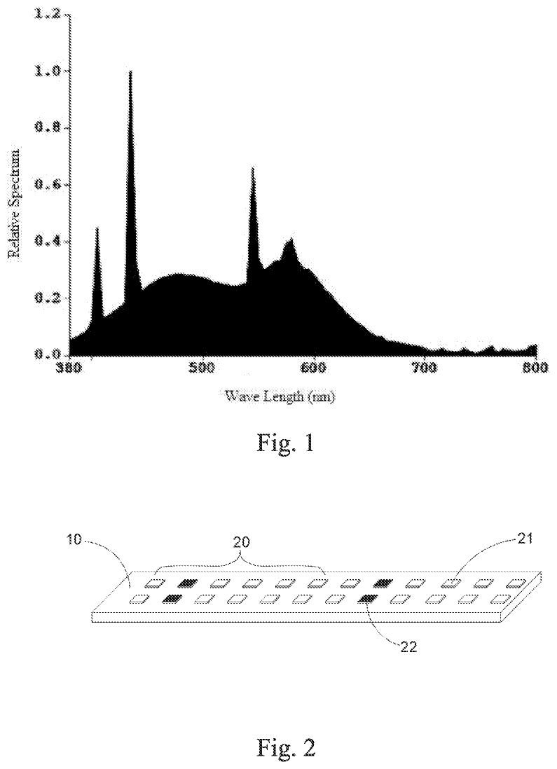

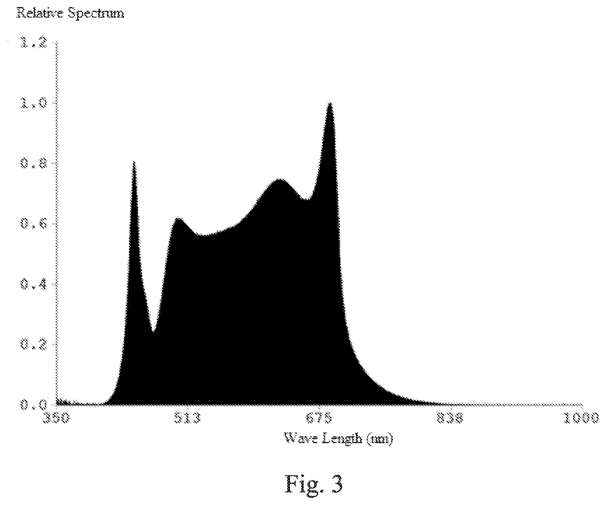

As shown in FIG. 2, the present application discloses a full-spectrum eye-protecting LED lamp panel structure, comprising a substrate 10, and multiple groups of SMD lamp bead groups 20 are arranged on the substrate 10. According to the structure and appearance of the lamp, the shape of the lamp panel can be designed as a circle, a triangle or a long strip. In this embodiment, the lamp panel structure shown in FIG. 2 is a rectangular structure, and four groups of SMD bead groups 20 are arranged on the lamp panel. The total number of beads in ach group of SMD bead groups 20 is 6, including 5 white light beads 21 with full spectrum (that is, the frequency range of the emitted light is below 350 nm-above 838 nm) and one red light bead 22 with a wavelength of 620-730 nm for adjusting spectrum. The surface of the white light beads 21 are provided with yellow phosphors, so that the light emitted by the white light bead 21 mainly takes 4000K color temperature as the center value, and closes to natural light as the main color temperature. FIG. 3 shows a spectrogram after the light emitted by the red lamp bead 22 is mixed with the light of other white light lamp beads 21. It can be seen from FIG. 3 that the relative spectral value of blue light with a frequency in the range of 350-513 nm is lower than the relative spectral value of blue light shown in FIG. 1. The blue light value in the spectrum of FIG. 3 can be lower than 0.8. It can be seen that, compared with the traditional LED lamp, the present application has the function of protecting eyes, and the color rendering index RA is greater than 96, and the effect of protecting eyes can be achieved by reducing blue light. For lamps with different shapes or lengths, the number of white light beads 21 included in each group of SMD light beads 20 is controlled within the range of 3-10 to ensure that the red light bead 22 used for blending are evenly blended with the light of the surrounding white light beads 21, the color temperature inconsistency is avoided. The white light bulbs 21 and the red light bulb 22 in the SMD bead group 20 are connected in series, and the positive and negative terminals of a power supply are connected in parallel between the SMD lamp bead groups 20. By adopting the combination of series and parallel mode, under the condition that the specifications of each bead are consistent, the voltage of all branches (that is, each group of SMD bead groups 20) is basically equal by adopting this connection method. The current flowing through each branch is basically the same, so that the brightness of each bead is consistent, so as to improve the eye protection effect. The overall series-parallel connection of the above-mentioned light source is combined with the input voltage and current of the lamp power supply to carry out a proportional design. The input power supply of the lamp design adopts high PF without stroboscopic, comfortable light waves that can be observed by the human eye, which significantly improves the effect of eye protection lighting. Since the lamp may be composed of different light-transmitting materials, the number of red light beads 22 selected according to the different light-emitting materials also needs to be adjusted. Generally, when PS, PC or PMMA is used as a single light-transmitting material, each group of SMD lamp beads 20 can be made of white light beads 21 and red light beads 22 in a ratio of 5 to 1 or 6 to 1. With the proportion, the full-spectrum eye protection function can be achieved. However, if the light-transmitting material adopts multilayer optical materials, the light distribution ratio needs to be changed. For example, the material of PS crystal plate+PC optical lens needs to add an additional proportion of red light beads 22 to the above ratio to achieve the full-spectrum eye protection function.

The present invention also discloses a lamp using the full-spectrum eye-protecting LED lamp panel structure, which can be ceiling lamps, desk lamps, floor lamps, panel lamps, classroom lamps, blackboard lamps, downlights, light strips, bulbs, etc. It meets different application scenarios or different user needs.

The above-mentioned embodiments are only preferred embodiments of the present application, which cannot limit the scope of protection of the present application. Any insubstantial changes and substitutions made by those skilled in the art on the basis of the present application fall within the scope of protection claimed by the present application.

What is claimed is:

1. A full-spectrum eye-protecting LED lamp panel structure, comprising a substrate on which multiple groups of SMD bead groups are arranged, and each group of the SMD bead groups comprises a plurality of full-spectrum white light beads and at least one red light beads with a wavelength of 620-730 nm for adjusting spectrum.

2. The full-spectrum eye-protecting LED lamp panel structure according to claim 1, wherein the number of the white light beads comprised in each group of the SMD bead group is 3-10 pieces.

3. The full-spectrum eye-protecting LED lamp panel structure according to claim 2, wherein the surface of the white light head is provided with yellow phosphors.

4. The full-spectrum eye-protecting LED lamp panel structure according to claim 1, wherein the white light beads and the red light beads in the SMD bead groups are connected in series, and the SMD bead groups are connected in parallel to positive and negative terminals of a power supply.

5. A lamp, wherein the lamp is provided with the full-spectrum eye-protecting LED lamp panel structure according to claim 1.
